(19) United States
(12) Patent Application Publication
(10) Pub. No.: US 2025/0221169 A1
(43) Pub. Date: Jul. 3, 2025

(54) DISPLAY APPARATUS

(71) Applicant: LG DISPLAY CO., LTD., Seoul (KR)

(72) Inventors: Wonrae KIM, Paju-si (KR); ByungGwan HYUN, Seoul (KR)

(73) Assignee: LG DISPLAY CO., LTD., Seoul (KR)

(21) Appl. No.: 18/735,745

(22) Filed: Jun. 6, 2024

(30) Foreign Application Priority Data
Dec. 29, 2023 (KR) 10-2023-0197551

(51) Int. Cl. H10K 59/122; H10K 59/40

(52) U.S. Cl. CPC H10K 59/122; H10K 59/40

(57) ABSTRACT

A display apparatus includes a substrate including a display area in which a plurality of pixels is defined and a non-display area which does not overlap the display area; a plurality of light emitting elements each including a first electrode, an emission layer, and a second electrode which are sequentially laminated on the substrate in the display area; and a bank disposed on the substrate and covering an edge of the first electrode, wherein at least a part of the bank includes a first bank layer being in contact with the edge of the first electrode and including an inner portion in a direction toward the first electrode with respect to a vertical line passing through a maximum height portion and an outer portion opposite to the inner portion; a second bank layer being in contact with the outer portion of the first bank layer; and a third bank layer disposed on the second bank layer, wherein the second bank layer is enclosed by at least one of the first bank layer and the third bank layer.

### CROSS-REFERENCE TO RELATED APPLICATION

This application claims the priority of Korean Patent Application No. 10-2023-0197551 filed on Dec. 29, 2023, which is hereby incorporated by reference in its entirety.

### BACKGROUND

### Field of the Disclosure

The present disclosure relates to a display apparatus, and more particularly, to a display apparatus capable of enhancing the reliability of a light emitting element.

### Description of the Background

As it enters the information era, a field of a display apparatus which visually expresses electrical information signals has been rapidly developed. Also, studies are continued to improve performances of various display apparatuses, such as reduced thickness, weight lightening, and low power consumption.

Examples of such display apparatuses may include a liquid crystal display (LCD), a field emission display (FED), an electro-wetting display (EWD), and an organic light emitting display (OLED).

Among various light emitting display apparatuses, an electroluminescent display apparatus is a self-emitting display apparatus so that a separate light source is not necessary unlike the LCD. Therefore, the electroluminescent display apparatus may be manufactured to have light weight and reduced thickness.

Since the electroluminescent display apparatus is driven at a low voltage, it is advantageous not only in terms of power consumption, but also in terms of color implementation, a response speed, a viewing angle, a contrast ratio (CR). Therefore, it is expected to be utilized in various fields.

### SUMMARY

Accordingly, the present disclosure is to provide a display apparatus which enhances the reliability of a light emitting element by suppressing oxidation and contamination of the surface of an electrode in the light emitting element.

The present disclosure is also to provide a light emitting display apparatus having a low reflection structure for a light emitting element.

The present disclosure is not limited to the above-mentioned, and other features, which are not mentioned above, may be clearly understood by those skilled in the art from the following descriptions.

The exemplary aspects of the present disclosure are not limited to the above-mentioned, and other features, which are not mentioned above, may be clearly understood by those skilled in the art from the following descriptions.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display apparatus includes a substrate including a display area in which a plurality of pixels is defined and a non-display area which does not overlap the display area; a plurality of light emitting elements each including a first electrode, an emission layer, and a second electrode which are sequentially laminated on the substrate in the display area; and a bank disposed on the substrate and covering an edge of the first electrode, wherein at least a part of the bank includes a first bank layer being in contact with the edge of the first electrode and including an inner portion in a direction toward the first electrode with respect to a vertical line passing through a maximum height portion and an outer portion opposite to the inner portion; a second bank layer being in contact with the outer portion of the first bank layer; and a third bank layer disposed on the second bank layer, wherein the second bank layer is enclosed by at least one of the first bank layer and the third bank layer.

In another aspect of the present disclosure, a display apparatus includes a substrate including a display area in which a plurality of pixels is defined; a light emitting element including a first electrode, an emission layer disposed on the first electrode and a second electrode disposed on the emission layer in the display area; a first bank layer being in contact with the first electrode and the light emitting layer and having an inner portion facing the light emitting element and an outer portion opposite to the inner portion; a second bank layer being in contact with the outer portion of the first bank layer; and a third bank layer being in contact the first bank layer and disposed on the second bank layer, wherein the first bank layer and the third bank layer enclose the second bank layer, wherein the second bank layer does not overlap the first electrode, and wherein the first bank layer and the second bank layer are formed of different materials, and the first bank layer and the third bank layer are formed of a same material.

Other detailed matters of the exemplary aspects are included in the detailed description and the drawings.

The display apparatus according to an exemplary aspect of the present disclosure may enhance the reliability by suppressing oxidation and contamination of the surface of an electrode in a light emitting element.

According to an exemplary aspect of the present disclosure, it is possible to selectively adjust a slope of a bank adjacent to an emission area of a sub-pixel. Thus, it is possible to secure a low reflection structure for a light emitting element and also possible to suppress the flow of an excessive light leakage current to a boundary between light emitting elements.

As described above, according to an exemplary aspect of the present disclosure, it is possible to minimize a potential probability of defects such as contamination or oxidation of the display apparatus. Therefore, a lifetime of the display apparatus may be improved, and, thus, production energy may be reduced, which enables driving with low power consumption.

The effects of the present disclosure are not limited to the aforementioned effects, and other effects, which are not mentioned above, will be apparently understood to a person having ordinary skill in the art from the following description.

It is to be understood that both the foregoing general description and the following detailed description are exemplary and explanatory and are intended to provide further explanation of the disclosure as claimed.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a block diagram of a display apparatus according to an exemplary aspect of the present disclosure;

FIG. 2 is a plan view of the display apparatus according to an exemplary aspect of the present disclosure;

FIG. 3 is a cross-sectional view taken along line I-I′ of FIG. 2, and shows one sub-pixel disposed in a display area of the display apparatus according to an exemplary aspect of the present disclosure;

FIG. 4A through FIG. 4G are cross-sectional views for explaining a process of forming a bank according to an exemplary aspect of the present disclosure;

FIG. 5A and FIG. 5B are cross-sectional views for explaining an example of a process of removing some layers of the bank according to an exemplary aspect of the present disclosure;

FIG. 6A and FIG. 6B are cross-sectional views for explaining another example of a process of removing some layers of the bank according to an exemplary aspect of the present disclosure;

FIG. 7 is a cross-sectional view illustrating an example of the shape of the bank according to an exemplary aspect of the present disclosure;

FIG. 8 is a cross-sectional view illustrating another example of the shape of the bank according to an exemplary aspect of the present disclosure;

FIG. 9 is a cross-sectional view illustrating yet another example of the shape of the bank according to an exemplary aspect of the present disclosure;

FIG. 10 is a cross-sectional view illustrating still another example of the shape of the bank according to an exemplary aspect of the present disclosure;

FIG. 11 is a cross-sectional view illustrating still another example of the shape of the bank according to an exemplary aspect of the present disclosure;

FIG. 12 is a cross-sectional view illustrating still another example of the shape of the bank according to an exemplary aspect of the present disclosure;

FIG. 13 is a cross-sectional view illustrating an example of the shape of the bank according to another exemplary aspect of the present disclosure;

FIG. 14 is a cross-sectional view illustrating another example of the shape of the bank according to another exemplary aspect of the present disclosure;

FIG. 15 is a cross-sectional view illustrating yet another example of the shape of the bank according to another exemplary aspect of the present disclosure;

FIG. 16 is a cross-sectional view illustrating still another example of the shape of the bank according to another exemplary aspect of the present disclosure; and

FIG. 17 is a cross-sectional view illustrating still another example of the shape of the bank according to another exemplary aspect of the present disclosure.

### DETAILED DESCRIPTION

Advantages and characteristics of the present disclosure and a method of achieving the advantages and characteristics will be clear by referring to exemplary aspects described below in detail together with the accompanying drawings. However, the present disclosure is not limited to the exemplary aspects disclosed herein but will be implemented in various forms. The exemplary aspects are provided by way of example only so that those skilled in the art may fully understand the disclosures of the present disclosure and the scope of the present disclosure.

The shapes, sizes, ratios, angles, numbers, and the like illustrated in the accompanying drawings for describing the exemplary aspects of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly” is not used.

When an element or layer is referred to as being “on” another element or layer, it may be directly on the other element or layer, or intervening elements or layers may be present therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure. Like reference numerals generally denote like elements throughout the specification.

Like reference numerals generally denote like elements throughout the specification.

A size and a thickness of each component illustrated in the drawings are illustrated for convenience of explanation, and are not limited to the size and the thickness of the component illustrated in aspects of the present disclosure.

The features of various aspects of the present disclosure may be partially or entirely coupled to or combined with each other and may be interlocked and operated in technically various ways, and respective aspects may be carried out independently of or in association with each other.

Hereinafter, an exemplary aspect of the present disclosure will be described in detail with reference to the drawings.

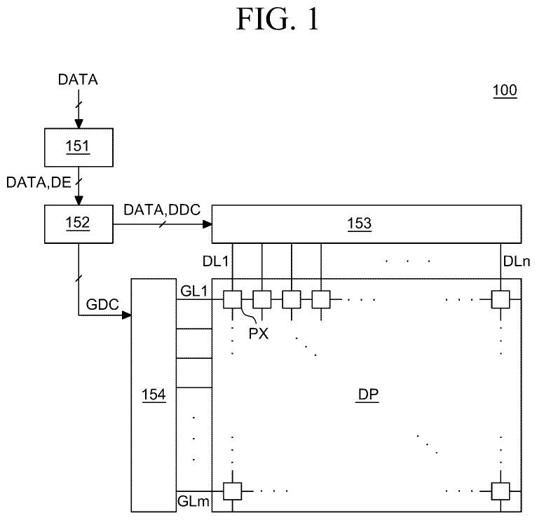

FIG. 1 is a block diagram of a display apparatus according to an exemplary aspect of the present disclosure.

Referring to FIG. 1, a display apparatus 100 according to an exemplary aspect of the present disclosure may include an image processor 151, a timing controller 152, a data driver 153, a gate driver 154, and a display panel DP.

The image processor 151 outputs a data signal DATA and a data enable signal DE supplied from the outside. The image processor 151 may output a driving signal including one or more of a vertical synchronization signal, a horizontal synchronization signal, and a clock signal in addition to the data enable signal DE.

The timing controller 152 receives the driving signal including the data enable signal DE, etc. and the data signal DATA from the image processor 151. The timing controller 152 outputs a gate timing control signal GDC for controlling operation timing of the gate driver 154 and a data timing control signal DDC for controlling operation timing of the data driver 153 based on the driving signal.

In response to the data timing control signal DDC supplied from the timing controller 152, the data driver 153 samples and latches the data signal DATA supplied from the timing controller 152. Then, the data driver 153 converts the sampled and latched data signal into a gamma reference voltage and outputs the gamma reference voltage. Also, the data driver 153 outputs the data signal through data lines DL1 to DLn.

The gate driver 154 outputs a gate signal while shifting a level of a gate voltage in response to the gate timing control signal GDC supplied from the timing controller 152. Also, the gate driver 154 outputs the gate signal through gate lines GL1 to GLm.

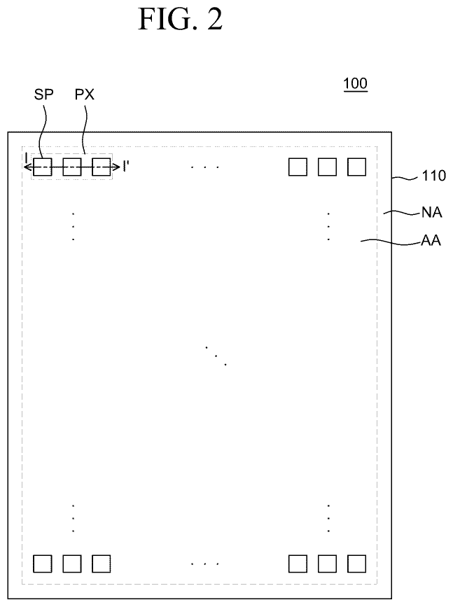

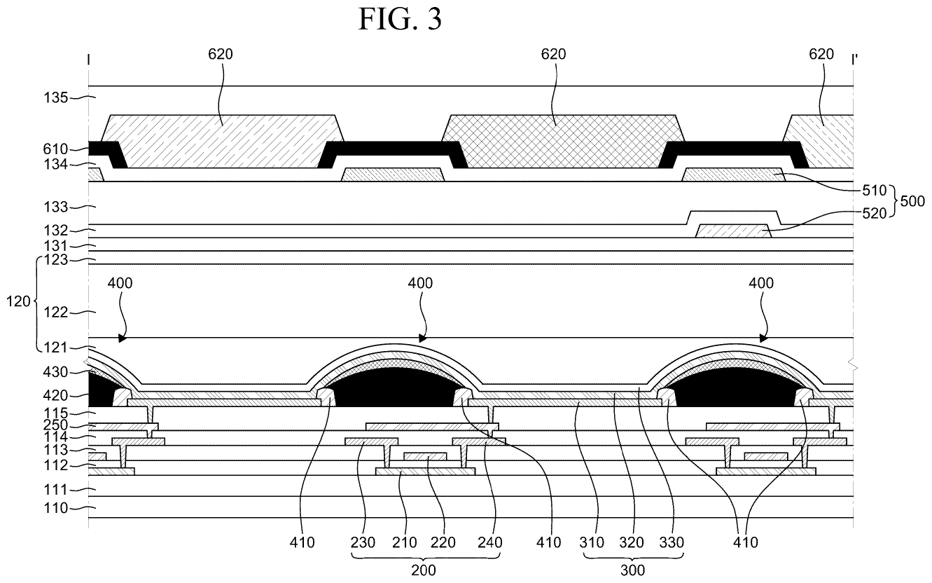

The display panel DP includes a plurality of pixels PX. Each of the plurality of pixels PX emits light and displays an image in response to the data signal and the gate signal supplied from the data driver 153 and the gate driver 154, respectively. A detailed structure of the pixel PX will be described in detail in FIG. 2 and FIG. 3.

FIG. 2 is a plan view of the display apparatus according to an exemplary aspect of the present disclosure.

As shown in FIG. 2, the display apparatus 100 according to an exemplary aspect of the present disclosure includes a substrate 110 in which the plurality of pixels PX is disposed. Herein, each pixel PX may be composed of a plurality of sub-pixels SP. FIG. 2 illustrates an example of a pixel PX including three sub-pixels SP which emit light of different colors from each other. For example, in the display apparatus 100 according to an exemplary aspect of the present disclosure, each pixel PX may include sub-pixels SP which emit red light (R), green light (G), and blue light (B), respectively. However, the number of sub-pixels SP included in a pixel PX is not limited thereto. For example, each pixel PX may further include a sub-pixel SP which emits white light in addition to the sub-pixels SP which emit red light (R), green light (G), and blue light (B), respectively.

The substrate 110 is configured to support various components included in the display apparatus 100. The substrate 110 may be made of an insulating material. Also, the substrate 110 may be made of a flexible material to be bendable. Further, the substrate 110 may be made of a transparent material. For example, the substrate 110 may be made of a plastic material such as polyimide (PI).

On the substrate 110, a plurality of gate lines GL extending in a first direction may intersect a plurality of data lines DL extending in a second direction different from the first direction. Herein, pixels PX are defined at respective intersections of the plurality of gate lines GL and the plurality of data lines DL on the substrate 110.

An area in which the plurality of pixels PX for implementing images on the substrate 110 is disposed may be referred to as a display area AA. An area which is disposed outside the display area AA and in which the plurality of pixels PX is not disposed may be referred to as a non-display area NA.

A display unit for displaying images and a circuit unit for driving the display unit may be provided in the display area AA. For example, if the display apparatus 100 is an organic light emitting display apparatus, the display unit may include an organic light emitting element. That is, the display unit may include an anode, an emission layer on the anode, and a cathode on the emission layer. Herein, the emission layer may be an organic emission layer, and may be composed of, for example, a hole transport layer, a hole injection layer, an organic emission layer, an electron injection layer, and an electron transport layer. However, if the display apparatus 100 is a liquid crystal display apparatus, the display unit may be configured to include a liquid crystal layer. Hereinafter, for convenience in explanation, the description will be made under the assumption that the display apparatus 100 is an organic light emitting display apparatus. However, the present disclosure is not limited thereto.

The circuit unit may include various transistors, capacitors, and lines for driving light emitting elements. Specifically, the circuit unit may be composed of various components such as a driving transistor, a switching transistor, a storage capacitor, a gate line, and a data line, but is not limited thereto.

For example, each sub-pixel SP of the display apparatus 100 according to an exemplary aspect of the present disclosure may include a switching transistor, a driving transistor, a capacitor, and a light emitting element.

The light emitting element may operate to emit light in response to a driving current generated by the driving transistor.

The switching transistor may be switched on/off so that a data signal supplied through the data line DL in response to a gate signal supplied through the gate line GL is stored in the capacitor as a data voltage.

The driving transistor may operate so that a constant driving current flows between a high potential power line and a low potential power line in response to the data voltage stored in the capacitor.

There has been described an example where each sub-pixel SP of the display apparatus 100 according to an exemplary aspect of the present disclosure has a 2T (transistor) 1C (capacitor) structure including a switching transistor, a driving transistor, and a capacitor. However, the sub-pixel SP may have various structures such as 3T1C, 4T2C, 5T2C, 6T1C, 6T2C, 7T1C, 7T2C, etc. when a compensation circuit is added.

The compensation circuit is configured to compensate a threshold voltage of the driving transistor. The compensation circuit may include at least one compensation thin film transistor and at least one compensation capacitor. The configurations and structures of the compensation thin film transistor and the compensation capacitor may vary depending on a compensation method.

The non-display area NA is an area in which no image is displayed, and various lines, circuits, etc. for driving the display unit disposed in the display area AA are disposed.

The non-display area NA may be defined as an area enclosing the display area AA as shown in FIG. 2, but is not limited thereto. The non-display area NA may be defined as an area extending from the display area AA. Also, the non-display area NA may be defined as an area extending from a plurality of sides of the display area AA.

Also, the non-display area NA may include a pad area provided to receive external electric power, a data driving signal, etc. or to transmit and receive a touch signal. In the pad area, an external module, for example, a driver IC such as a data driver integrated circuit (IC) or a gate driver IC, may be disposed.

The driver IC disposed in the pad area may be connected to a plurality of lines, and may be connected to the plurality of data lines DL or the plurality of gate lines GL disposed in the display area AA through the plurality of lines. That is, the driver IC disposed in the pad area may be electrically connected to each of the plurality of pixels PX.

In the non-display area NA, a bending area which is a part of the non-display area NA to be bendable in one direction may be located between the display area AA and the pad area. Since the non-display area NA is an area in which no image is displayed, it does not need to be seen on an upper surface of the substrate 110. Thus, a part of the non-display area NA of the substrate 110 may be bent. For example, an edge on one side of the substrate 110 may be bent in a back surface direction to have a predetermined curvature. Herein, the pad area may be located to overlap the display area AA in the back surface direction of the display area AA. Therefore, it is possible to reduce the secure the non-display area NA while securing an area for lines and a driving circuit.

FIG. 3 is a cross-sectional view taken along line I-I′ of FIG. 2, and shows one sub-pixel disposed in a display area of the display apparatus according to an exemplary aspect of the present disclosure.

Referring to FIG. 3, the display apparatus 100 according to an exemplary aspect of the present disclosure may include the substrate 110, a buffer layer 111, a thin film transistor 200, and a gate insulating layer 112. Also, the display apparatus 100 may include a first interlayer insulating layer 113, a second interlayer insulating layer 114, a connection electrode 250, a planarization layer 115, a light emitting element 300, a bank 400, and an encapsulation layer 120. Further, the display apparatus 100 may include a touch buffer layer 131, a touch insulating layer 132, an organic insulating layer 133, a touch sensor 500, a touch electrode protection layer 134, a light shielding layer 610, a color filter 620, and an overcoating layer 135. Herein, the encapsulation layer 120 is composed of a plurality of layers, and includes a first inorganic encapsulation layer 121, an organic encapsulation layer 122, and a second inorganic encapsulation layer 123. Also, the thin film transistor 200 includes a semiconductor layer 210, a gate electrode 220, a source electrode 230, and a drain electrode 240. Further, the light emitting element 300 includes a first electrode 310 serving as an anode, an emission layer 320, and a second electrode 330 serving as a cathode. Furthermore, the bank 400 is composed of a plurality of layers, and includes a first bank layer 410, a second bank layer 420, and a third bank layer 430.

The substrate 110 serves to support and protect the components disposed thereon. The substrate 110 may be a rigid substrate, or a flexible substrate capable of being bent, folded and rolled.

When the substrate 110 is made of a plastic material having flexibility, it may be made of, for example, polyimide (PI). When the substrate 110 is made of polyimide (PI), a manufacturing process of the display apparatus 100 is performed in a state where a support substrate made of glass is disposed under the substrate 110. After the manufacturing process of the display apparatus 100 is completed, the support substrate may be released.

Also, a back plate for supporting the substrate 110 may be disposed under the substrate 110 after the support substrate is released. For example, when the back plate is further disposed under the substrate 110, the back plate may not be disposed in a portion overlapping the bending area of the substrate 110, but is not limited thereto.

When the substrate 110 is made of polyimide (PI), moisture may permeate through the substrate 110 made of polyimide (PI) to the thin film transistor 200 or the light emitting element 300. Thus, performance of the display apparatus 100 may be degraded. Therefore, the substrate 110 of the display apparatus 100 according to an exemplary aspect of the present disclosure may be made of double polyimides (PI) to suppress the degradation of performance of the display apparatus 100 caused by moisture permeation.

Also, the display apparatus 100 according to an exemplary aspect of the present disclosure may further include an inorganic film disposed between the double polyimides (PI) of the substrate 110. Therefore, the product reliability may be improved by blocking electric charges charged in a lower polyimide (PI). Further, a process of forming a metal layer to block the electric charges charged in the polyimide (PI) may be omitted. Therefore, the overall process may be simplified and the production cost may be reduced. For example, the inorganic film between the double polyimides (PI) may be an inorganic insulating filmi configured by a single layer of silicon nitride (SiNx) or silicon oxide (SiOx), or a multi-layer thereof.

The buffer layer 111 may be disposed on the substrate 110. Herein, the buffer layer 111 may be a multi-buffer layer including a plurality of inorganic films.

The semiconductor layer 210 of the thin film transistor 200 is disposed on the buffer layer 111. The buffer layer 111 may be configured to protect the semiconductor layer 210 and enhance an interface adhesive force of the semiconductor layer 210.

The display apparatus 100 according to an exemplary aspect of the present disclosure may further include a metal layer disposed under one of the plurality of films of the buffer layer 111. The metal layer may serve as a light shield.

The thin film transistor 200 may be disposed on the buffer layer 111. The thin film transistor 200 includes the semiconductor layer 210, the gate electrode 220, the source electrode 230, and the drain electrode 240. The source electrode 230 may serve as a drain electrode and the drain electrode 240 may serve as a source electrode depending on the design of a pixel circuit.

The semiconductor layer 210 may include a channel region overlapping the gate electrode 220, and a first region and a second region respectively located on both sides of the channel region and connected to the source electrode 230 and the drain electrode 240.

The gate insulating layer 112 is disposed on the semiconductor layer 210 and serves to insulate the semiconductor layer 210 from the gate electrode 220. The gate insulating layer 112 may cover the semiconductor layer 210 and may be provided on a front surface of the display area AA. The gate insulating layer 112 may be made of an inorganic insulating material, such as silicon oxide (SiO₂), silicon nitride (SiNx), and silicon oxynitride (SiON), or a multi-layer thereof, but is not limited thereto.

The gate electrode 220 is disposed on the gate insulating layer 112, and overlaps the semiconductor layer 210 with the gate insulating layer 112 interposed therebetween. The gate electrode 220 may be configured by a single layer of one of molybdenum (Mo), aluminum (Al), chrome (Cr), gold (Au), titanium (Ti), nickel (Ni), neodymium (Nd), and copper (Cu) or an alloy thereof, or a multi-layer thereof, but is not limited thereto.

The interlayer insulating layer 113 is disposed on the gate electrode 220. The interlayer insulating layer 113 may cover the gate electrode 220 and may be formed on the front surface of the display area AA. The interlayer insulating layer 113 may be made of the same inorganic insulating material, for example, silicon oxide (SiO₂), silicon nitride (SiNx), or silicon oxynitride (SiON), as the gate insulating layer 112, or a multi-layer thereof, but is not limited thereto.

The source electrode 230 and the drain electrode 240 are disposed to be spaced apart from each other on the interlayer insulating layer 113. The source electrode 230 and the drain electrode 240 are electrically connected to the semiconductor layer 210 through contact holes penetrating through the interlayer insulating layer 113 and the gate insulating layer 112.

FIG. 3 illustrates that the thin film transistor 200 is a top gate type in which the gate electrode 220 is located on the semiconductor layer 210, but the present disclosure is not limited thereto. That is, the thin film transistor 200 may be a bottom gate type in which the gate electrode 220 is located under the semiconductor layer 210, or a double gate type in which the gate electrode 220 is located both on and under the semiconductor layer 210.

Also, FIG. 3 illustrates one thin film transistor 200 corresponding to one sub-pixel SP. However, the number and types of thin film transistors 200 corresponding to one sub-pixel SP are not limited thereto. For example, FIG. 3 illustrates, as the thin film transistor 200, only a driving transistor for driving the light emitting element 300. However, each sub-pixel SP may further include a switching transistor corresponding to the light emitting element.

The connection electrode 250 may be disposed on the thin film transistor 200. The second interlayer insulating layer 114 may be disposed between the thin film transistor 200 and the connection electrode 250 on the front surface of the display area AA.

The connection electrode 250 is connected to the drain electrode 240 of the thin film transistor 200 through a contact hole penetrating through the second interlayer insulating layer 114.

The planarization layer 115 is disposed on the connection electrode 250 on the front surface of the display area AA. The planarization layer 115 is configured to planarize the first electrode 310 of the light emitting element 300 partitioned by the bank 400. For example, the planarization layer 115 may be made of resin such as photo acryl and polyimide (PI).

The light emitting element 300 is disposed on the planarization layer 115. The light emitting element 300 may include the first electrode 310, the emission layer 320, and the second electrode 330 which are sequentially laminated. The first electrode 310 disposed on the planarization layer 115 is connected to the connection electrode 250 through a contact hole penetrating through the planarization layer 115. Thus, the first electrode 310 is electrically connected to the thin film transistor 200.

Hereinafter, there will be described an example where the display apparatus 100 according to an exemplary aspect of the present disclosure is a top emission type in which light is emitted to above the substrate 110 on which the light emitting element 300 is disposed. Herein, the first electrode (i. e., an anode) 310 of the light emitting element 300 may further include a transparent conductive layer and a reflective layer on the transparent conductive layer. The transparent conductive layer may be made of a transparent conductive material such as ITO and IZO. The reflective layer may be made of, for example, silver (Ag), aluminum (Al), gold (Au), molybdenum (Mo), tungsten (W), chrome (Cr) or an alloy thereof.

Also, the bank 400 which partitions the plurality of sub-pixels SP is disposed on the planarization layer 115. That is, the bank 400 is disposed on the planarization layer 115, and includes an opening in a portion overlapping the light emitting element 300 of each sub-pixel SP to expose a part of the first electrode 310 of the light emitting element 300.

The bank 400 of the display apparatus 100 according to an exemplary aspect of the present disclosure is composed of a plurality of layers. The bank 400 includes the first bank layer 410 in direct contact with the first electrode 310 of the light emitting element 300 and the second bank layer 420 in contact with a part of the first bank layer 410. Also, the bank 400 includes the third bank layer 430 covering all of the second bank layer 420 and at least a part of the first bank layer 410.

For example, each of the first bank layer 410, the second bank layer 420, and the third bank layer 430 may be made of an organic material. According to an exemplary aspect of the present disclosure, each of the first bank layer 410, the second bank layer 420, and the third bank layer 430 is made of an organic material. Therefore, these bank layers have a higher degree of freedom of shape than a bank made of an inorganic material. Also, it is easy to regulate the height, width and slope of each bank layer. For example, it is possible to minimize damage to the first electrode 310 during the manufacturing process. However, the present disclosure is not limited thereto.

For example, the first bank layer 410 may be made of an organic insulating material, and may be made of a transparent material. The first bank layer 410 may be formed when a part of a photo resist PR coated on a metal pattern for forming the first electrode 310 of the light emitting element 300 remains during a process of preparing the bank 400.

The first bank layer 410 may be made of a positive photosensitive material, for example, a polyimide-based polymer.

The first bank layer 410 may be in contact with an end point (or edge) of the first electrode 310 of the light emitting element 300. Herein, the first bank layer 410 includes an inner portion in a direction toward the first electrode 310 based on a vertical line passing through a maximum height portion and an outer portion opposite to the inner portion.

The second bank layer 420 may be a black bank containing a light shielding black material such as a black pigment or the like. The second bank layer 420 may cover all of an area (i.e., a non-emission area) not overlapping the first electrode 310 of the light emitting element 300. Also, the second bank layer 420 may suppress optical interference between sub-pixels SP adjacent to each other.

The second bank layer 420 may be made of a material having different optical properties from the first bank layer 410, i.e., a negative photosensitive material, for example, an epoxy-based polymer.

The second bank layer 420 is disposed on the planarization layer 115 to be in contact with the outer portion of the first bank layer 410.

The third bank layer 430 is disposed on the second bank layer 420 to cover the second bank layer 420. Also, the third bank layer 430 is disposed to be in contact with the outer portion of the first bank layer 410.

The third bank layer 430 may be made of the same material as the first bank layer 410, but is not limited thereto. The third bank layer 430 and the first bank layer 410 may be made of a material suitable for patterning an electrode (i.e., metal) of the light emitting element from among materials which release a small amount of outgas and have high reliability.

That is, as shown in FIG. 3, the second bank layer 420 may be enclosed by at least one of the first bank layer 410 and the third bank layer 430. Therefore, the first electrode 310 of the light emitting element 300 is not exposed at all during the process of preparing the second bank layer 420. Thus, a process and a material which may cause oxidation or contamination of the first electrode 310 do not affect the first electrode 310.

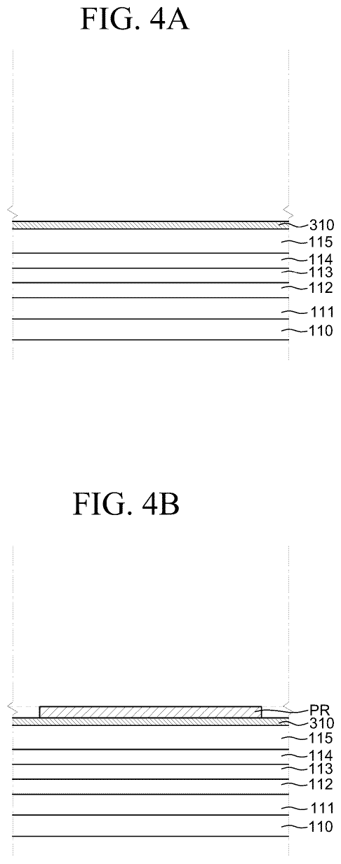

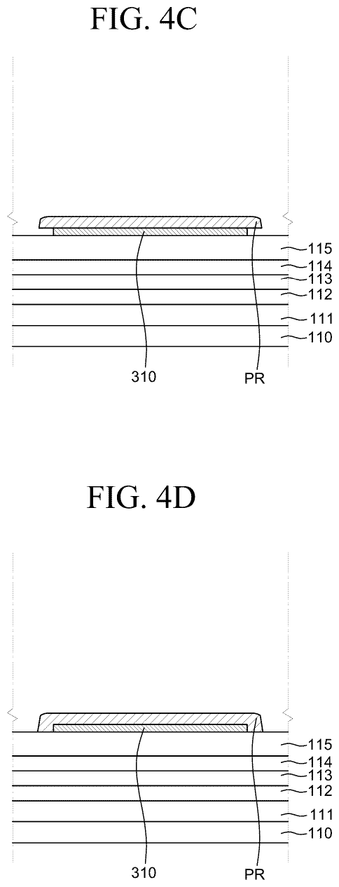

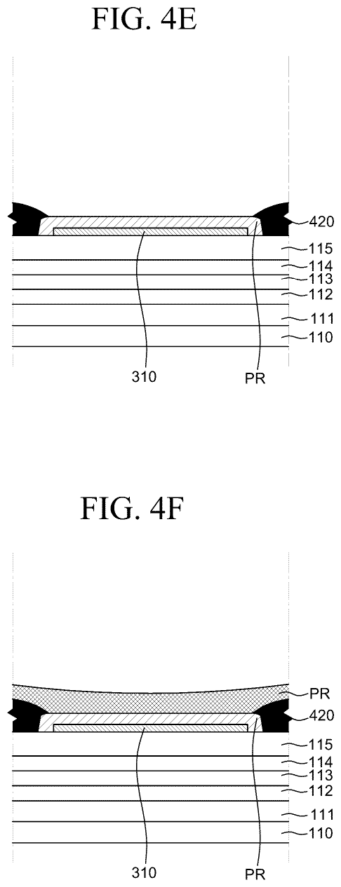

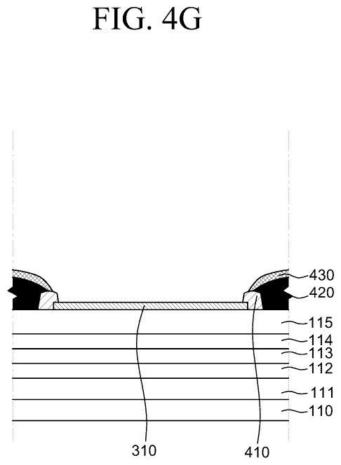

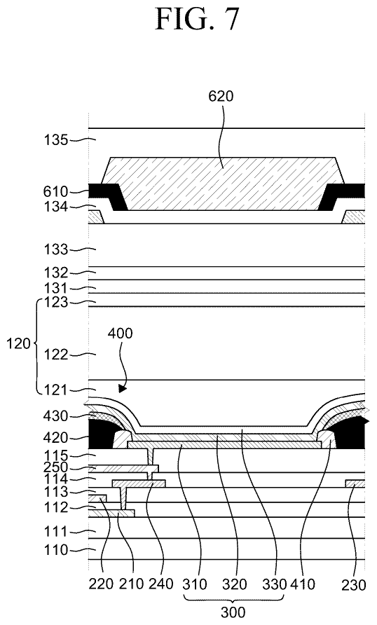

The process of preparing the bank 400 including the plurality of layers according to an exemplary aspect of the present disclosure will be described in detail with reference to FIG. 4 through FIG. 6B. Also, the structure of the bank 400 including the plurality of layers will be described in detail with reference to FIG. 7 through FIG. 17.

The encapsulation layer 120 is disposed on the light emitting element 300 and the bank 400.

FIG. 3 illustrates an example where the emission layer 320 and the second electrode 330 of the light emitting element 300 are sequentially laminated on the first electrode 310 and disposed to cover an upper portion of the bank 400. Herein, the encapsulation layer 120 covers the light emitting element 300 and is disposed on the front surface of the display area AA. However, the emission layer 320 and the second electrode 330 of the light emitting element 300 may be located inside the opening of the bank 400, and may be disposed outside the opening of the bank 400 to overlap a part of the bank 400. In this case, the encapsulation layer 120 may be disposed to be in direct contact with the bank 400 as well as the light emitting element 300.

The encapsulation layer 120 may have a single layer structure or a multi-layer structure. For example, as shown in FIG. 3, the encapsulation layer 120 may have a structure in which the first inorganic encapsulation layer 121, the organic encapsulation layer 122, and the second inorganic encapsulation layer 123 are sequentially laminated. In this case, the organic encapsulation layer 122 may have the greatest thickness and serve as a planarization layer.

The first inorganic encapsulation layer 121 may be disposed on the second electrode 330 to be most adjacent to the light emitting element 300. The first inorganic encapsulation layer 121 may be made of an inorganic insulating material suitable for low temperature deposition. For example, the first inorganic encapsulation layer 121 may be made of silicon nitride (SiNx), silicon oxide (SiOx), silicon oxynitride (SiON), or aluminum oxide (Al₂O₃). Since the first inorganic encapsulation layer 121 is deposited in a low temperature atmosphere, it is possible to suppress damage to the emission layer 320 containing an organic material, which is vulnerable to a high temperature, during the deposition process.

The organic encapsulation layer 122 may be disposed on the first inorganic encapsulation layer 121 to cover the front surface of the display area AA. Also, the organic encapsulation layer 122 may serve to buffer stress generated among layers during bending of the flexible display apparatus 100 and enhance planarization performance. The organic encapsulation layer 122 have a smaller area than the first inorganic encapsulation layer 121. In this case, the organic encapsulation layer 122 may be disposed to expose both end point (or edge)s (or edges) of the first inorganic encapsulation layer 121. For example, the organic encapsulation layer 122 may be made of an organic insulating material such as acryl resin, epoxy resin, polyimide, polyethylene, and silicon oxycarbon (SiOC). Also, the organic encapsulation layer 122 may be prepared by an inkjet method, but is not limited thereto.

The second inorganic encapsulation layer 123 is disposed on the organic encapsulation layer 122. Herein, the second inorganic encapsulation layer 123 may minimize or block the permeation of external moisture or oxygen into the first inorganic encapsulation layer 121 and the organic encapsulation layer 122. To this end, the second inorganic encapsulation layer 123 may be disposed to cover upper and side surfaces of the organic encapsulation layer 122 and the first inorganic encapsulation layer 121. For example, the second inorganic encapsulation layer 123 may be made of an inorganic insulating material such as silicon nitride (SiNx), silicon oxide (SiOx), silicon oxynitride (SiON), and aluminum oxide (Al₂O₃).

Meanwhile, in the non-display area NA of the display apparatus 100 according to an exemplary aspect of the present disclosure, one or more shielding structures may be disposed to block the flow of the organic encapsulation layer 122 constituting the encapsulation layer 120. For example, each of the shielding structures may be formed into a dam having a predetermined height capable of blocking the flow of the organic encapsulation layer 122. Also, each of the shielding structures be disposed in the non-display area NA to have a closed curve shape enclosing the display area AA. Herein, the first inorganic encapsulation layer 121 and the second inorganic encapsulation layer 123 are disposed on the shielding structures, the flow of the organic encapsulation layer 122 may be blocked by the shielding structures. The shielding structures needs to have a predetermined height or more to block the flow of the organic encapsulation layer 122. Each of the shielding structures may be composed of at least one layer made of an organic material. For example, each of the shielding structures may include a lower layer made of the same material as the planarization layer 115 and an upper layer made of the same material as at least one of the first to third bank layers 410, 420 and 430 of the bank 400, but is not limited thereto.

In the display apparatus 100 according to an exemplary aspect of the present disclosure, at least one of a touch sensor layer and a color filter layer may be disposed on the encapsulation layer 120.

The touch sensor layer may include the touch buffer layer 131, the touch insulating layer 132, the organic protection layer 133, the touch sensor 500, and the touch electrode protection layer 134. The touch sensor 500 may include a plurality of touch electrodes 510 and a plurality of bridge electrodes 520.

Specifically, the touch buffer layer 131 may be disposed on the second inorganic encapsulation layer 123 of the encapsulation layer 120, and the touch sensor 500 may be disposed on the touch buffer layer 131.

The touch buffer layer 131 covers the encapsulation layer 120 and thus may protect the encapsulation layer 120 and suppress moisture permeation. Also, the touch buffer layer 131 may serve to reduce a parasitic capacitance between the second electrode 330 of the light emitting element 300 and a touch electrode included in the touch sensor 500.

The touch buffer layer 131 may be made of an organic insulating material, which may be formed at a low temperature of, for example, 100° C. or lower and has a low dielectric constant of 1 to 3, to suppress damage to the emission layer 320 containing an organic material vulnerable to a high temperature. For example, the touch buffer layer 131 may be made of an acryl-based, epoxy-based or siloxane-based material. Also, when the display apparatus 100 having flexibility is bent, the electrode (i. e., metal) of the touch sensor 500 located on the touch buffer layer 131 has a risk of being damaged. However, the touch buffer layer 131 made of an organic material may suppress damage to the encapsulation layer 120 and the metal constituting the touch sensor 500.

The touch sensor 500 may include a touch electrode 510 and a bridge electrode 520 disposed on different layers from each other. The touch insulating layer 132 may be disposed between the touch electrode 510 and the bridge electrode 520. That is, the bridge electrode 520 may be disposed on the touch buffer layer 131, the touch insulating layer 132 may be disposed on the bridge electrode 520, and the touch electrode 510 may be disposed on the touch insulating layer 132. The touch insulating layer 132 may be configured by an inorganic layer made such as metal oxide, metal oxynitride, silicon oxide, silicon nitride, and silicon oxynitride, or an organic layer, but is not limited thereto.

The organic protection layer 133 may be further disposed on the touch insulating layer 132 between the touch electrode 510 and the bridge electrode 520.

FIG. 3 illustrates a plurality of first touch electrodes 510 disposed adjacent to each other along a first direction, and a first bridge electrode 520 electrically connecting first touch electrodes 510 adjacent to each other among the plurality of first touch electrodes 510. FIG. 3 does not illustrate a portion where the touch electrode 510 and the bridge electrode 520 are electrically connected to each other. However, FIG. 3 is just a cross-sectional view of a part on the plane of the substrate 110. For example, two touch electrodes 510 adjacent to each other may be connected to one bridge electrode 520 through contact holes penetrating through the touch insulating layer 132.

Meanwhile, the display apparatus 100 according to an exemplary aspect of the present disclosure may further include a plurality of second touch electrodes disposed adjacent to each other along a second direction different from the first direction, and second bridge electrodes electrically connecting second touch electrodes adjacent to each other among the plurality of second touch electrodes. For example, one of the first touch electrode and the second touch electrode may serve as a sensing input electrode and the other touch electrode may serve as a sensing output electrode. Also, the first touch electrode and the second touch electrode may be electrically insulated from each other, and may be dispersed in a mesh form so as not to overlap each other.

Each of the touch electrodes 510 of the touch sensor 500 may be disposed overlapping the bank 400.

The touch electrode protection layer 134 may be disposed on the touch sensor 500, and the touch electrode protection layer 134 covers the plurality of touch electrodes 510 so as not to be exposed to the outside. For example, the touch electrode protection layer 134 may contain an inorganic material, such as silicon nitride (SiNx) or silicon oxide (SiO₂), or polyacrylates resin, polyimides resin, and an acryl-based organic material, but is not limited thereto.

The color filter layer may include the light shielding layer 610 and the color filter 620.

The light shielding layer 610 overlaps the bank 400, and includes a plurality of openings, each of which overlaps the opening of the bank 400. For example, the light shielding layer 610 may have a smaller width than the bank 400, and each opening of the light shielding layer 610 may have a greater width than the corresponding opening of the bank 400.

The light shielding layer 610 suppresses recognition of external light incident from the outside and reflected by lines of the display apparatus 100. The light shielding layer 610 may be located to overlap an edge of an area (i.e., an emission area) in which the light emitting element is disposed. Thus, the light shielding layer 610 may reduce the amount of external light incident into the emission area by absorbing the external light. For example, the light shielding layer 610 may be a black matrix containing a black material.

The color filter 620 is located on the light shielding layer 610. Most of the color filter 620 may overlap the opening of the light shielding layer 610 and a part of the color filter 620 may overlap the light shielding layer 610. For example, the color filter 620 may be formed filling in the opening of the light shielding layer 610 as shown in FIG. 3.

The color filter 620 suppresses reflection and recognition of external light incident from the outside into the bank 400. Since the color filter 620 cannot completely block light, it may suppress recognition of reflected light of external light while not reducing the efficiency of light emitted from the emission layer 320 of the light emitting element 300.

Also, the emission layer 320 of the light emitting element 300 included in the plurality of sub-pixels SP in the display apparatus 100 according to an exemplary aspect of the present disclosure may output white light. In this case, the color filters 620 respectively corresponding to the plurality of sub-pixels SP included in one pixel PX shown in FIG. 3 may include a red color filter which converts white light into red light, a blue color filter which converts white light into blue light, and a green color filter which converts white light into green light.

The overcoating layer 135 may be disposed on the color filter layer.

The overcoating layer 135 may cover the light shielding layer 610 and the color filter 620 to provide a flat surface to an upper portion. Also, the overcoating layer 135 may suppress contamination of the upper portion by various pigments which may be contained in the color filter 620. For example, the overcoating layer 135 may be made of acryl-based resin or epoxy-based resin. Alternatively, the overcoating layer 135 may be made of the same material as the planarization layer 115.

Further, the display apparatus 100 according to an exemplary aspect of the present disclosure may further include a cover glass disposed on the overcoating layer 135. The cover glass may be bonded to the overcoating layer 135 by an adhesive layer. Adhesive layers serving to bond various components of the display apparatus 100 to each other as well as the adhesive layer bonding the cover glass to the overcoating layer 135 may be made of an optically transparent display adhesive. The optically transparent display adhesive may include, for example, pressure sensitive adhesive, optical clear adhesive (OCR), or optical clear resin, but is not limited thereto.

The cover glass may protect the components of the display apparatus 100 from external impacts and suppress damage such as scratches.

Hereinafter, the process of preparing the bank 400 of the display apparatus 100 according to an exemplary aspect of the present disclosure will be described in more detail with reference to FIG. 4 through FIG. 6B.

FIG. 4A through FIG. 4G are cross-sectional views for explaining a process of forming a bank according to an exemplary aspect of the present disclosure.

First, referring to FIG. 4A, a metal layer is provided on the planarization layer 115 to form the first electrode 310 (i.e., anode) of the light emitting element 300.

FIG. 4B through FIG. 6B as well as FIG. 4A illustrate a structure in which the buffer layer 111, the gate insulating layer 112, the first interlayer insulating layer 113, the second interlayer insulating layer 114, and the planarization layer 115 are sequentially laminated on the substrate 110 of the display apparatus 100 shown in FIG. 3. In a state where the planarization layer 115 is laminated on the substrate 110, the first electrode 310 and the bank 400 are provided on the planarization layer 115.

For convenience in explanation, FIG. 4A through FIG. 6B do not illustrate other components than the plurality of layers laminated on the substrate 110. However, substantially the same components as the thin film transistor 200 and the connection electrode 250 shown in FIG. 3 may be further disposed between the substrate 110 and the planarization layer 115. In this case, as shown in FIG. 3, the first electrode 310 is connected to the connection electrode 250 through a contact hole penetrating through the planarization layer 115.

Then, referring to FIG. 4B, the photo resist PR is coated on an upper surface of the metal layer for forming the first electrode 310 of the light emitting element 300. Thereafter, the photo resist PR is exposed and developed by using a mask corresponding in shape to an electrode pattern to be formed.

A part of the photo resist PR coated on the upper surface of the metal layer for forming the first electrode 310 remains in contact with the first electrode 310 even after the end of the process of preparing the bank to be described later. The remaining part of the photo resist PR is the first bank layer 410.

The photo resist PR coated on the upper surface of the metal layer for forming the first electrode 310 may be made of a positive photosensitive material which remains where it has not been exposed to light.

Then, referring to FIG. 4C, the metal layer exposed to the outside of the photo resist PR remaining after development is etched to pattern the first electrode 310 of the light emitting element 300. For example, the metal layer may be etched by wet etching.

Thereafter, referring to FIG. 4D, the photo resist PR coated on the pattern of the first electrode 310 is cured. The curing process is performed at a predetermined temperature. Accordingly, as shown in FIG. 4D, a reflow process is performed to the photo resist PR coated on the pattern of the first electrode 310. Thus, the photo resist PR is stably bonded while covering not only an upper surface but also a side surface of the pattern of the first electrode 310.

Then, referring to FIG. 4E, in a state where the photo resist PR covering the pattern of the first electrode 310 is not stripped but maintained, a material layer for forming the second bank layer 420 (i.e., a black bank) is coated on the planarization layer 115 and the first electrode 310. Then, the material layer is etched such that the second bank layer 420 is brought into contact with a part of the photo resist PR and most of an upper surface of the photo resist PR (i.e., an upper surface of the first electrode 310) is exposed. For example, the material layer for forming the second bank layer 420 may be etched by plasma ashing.

Accordingly, the photo resist PR on the pattern of the first electrode 310 serves as a shield layer. Thus, it is possible to suppress direct contamination on the surface of first electrode 310 caused by the material layer for forming the second bank layer 420. Also, it is possible to suppress damage to the first electrode 310 which may occur during the process of etching the material layer for forming the second bank layer 420. Therefore, the device reliability may be improved.

The material layer for forming the second bank layer 420 may be made of a material having different optical properties from the photo resist PR coated on the upper surface of the metal layer for forming the first electrode 310. The material layer may be made of, for example, a negative photosensitive material which remains where it has been exposed to light. Also, the material layer for forming the second bank layer 420 may contain a black material.

Thereafter, referring to FIG. 4F, a material layer for forming the third bank layer 430 is coated on the second bank layer 420 and the photo resist PR. Herein, the material layer for forming the third bank layer 430 may be made of the same material as the photo resist PR, but is not limited thereto. For example, each of the first and third bank layers 410 and 430 may be made of a transparent material.

Then, referring to FIG. 4G, the photo resist PR on the pattern of the first electrode 310 and the material layer PR corresponding to the third bank layer 430 are removed. Accordingly, the bank 400 is formed. The bank 400 is composed of the first bank layer 410 in contact with the end point (or edge) of the first electrode 310, the second bank layer 420 in contact with the outer portion of the first bank layer 410, and the third bank layer 430 covering all of the second bank layer 420 and being in contact with at least a part of the first bank layer 410.

By performing the process of removing the photo resist PR on the pattern of the first electrode 310 and the material layer PR corresponding to the third bank layer 430 as shown in FIG. 4F and FIG. 4G, all of contaminants are removed together with the photo resist PR on the pattern of the first electrode 310. Therefore, the device reliability may be greatly improved.

For example, the process of removing the photo resist PR on the pattern of the first electrode 310 and the material layer PR corresponding to the third bank layer 430 may be an exposure and development process using a halftone mask. Accordingly, a slope of a portion adjacent to the first electrode 310 in the bank 400 may be selectively adjusted. Thus, it is possible to secure a low reflection structure for a light emitting element and also possible to suppress the flow of an excessive light leakage current between light emitting elements.

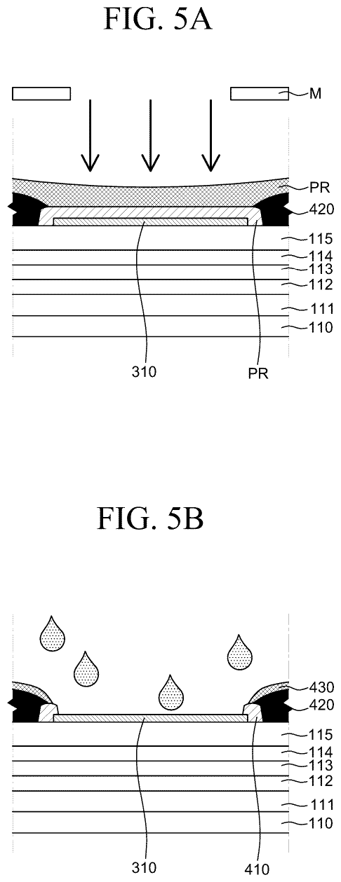

FIG. 5A and FIG. 5B are cross-sectional views for explaining an example of a process of removing some layers of the bank according to an exemplary aspect of the present disclosure.

First, referring to FIG. 5A, in a state where the material layer for forming the third bank layer 430 is coated on the second bank layer 420 and the photo resist PR as shown in FIG. 4F, exposure is performed using a halftone mask M which exposes the pattern of the first electrode 310.

Then, referring to FIG. 5B, a development and ashing processing is performed to the photo resist PR on the exposed pattern of the first electrode 310 and the material layer PR corresponding to the third bank layer 430.

Each of the photo resist PR on the pattern of the first electrode 310 and the material layer PR corresponding to the third bank layer 430 may be made of a positive photosensitive material. Thus, portions corresponding to a non-transmissive area and a semi-transmissive area of the halftone mask M remain and a portion corresponding to a transmissive area of the halftone mask M and overlapping the first electrode 310 is removed. Herein, the photo resist PR and the material layer PR corresponding to the third bank layer 430 in the semi-transmissive area may be laminated to a smaller height than those in the non-transmissive area of the halftone mask M. Through the halftone mask process, heights and slopes of the first bank layer 410 and third bank layer 430 adjacent to the first electrode 310 may be adjusted. For example, the first bank layer 410 may be tapered and its slope may be selectively adjusted.

Meanwhile, the second bank layer 420 may be made of a material, i.e., a negative photosensitive material, having different optical properties from the photo resist PR on the pattern of the first electrode 310 and the material layer PR corresponding to the third bank layer 430. However, as shown in FIG. 5A, the second bank layer 420 is entirely covered by the material layer PR corresponding to the third bank layer 430 and thus is not affected by light exposure. Also, the second bank layer 420 may be made of a material which is not damaged by a developer (e.g., an alkaline developer). The developer develops the photo resist PR on the pattern of the first electrode 310 and the material layer PR corresponding to the third bank layer 430.

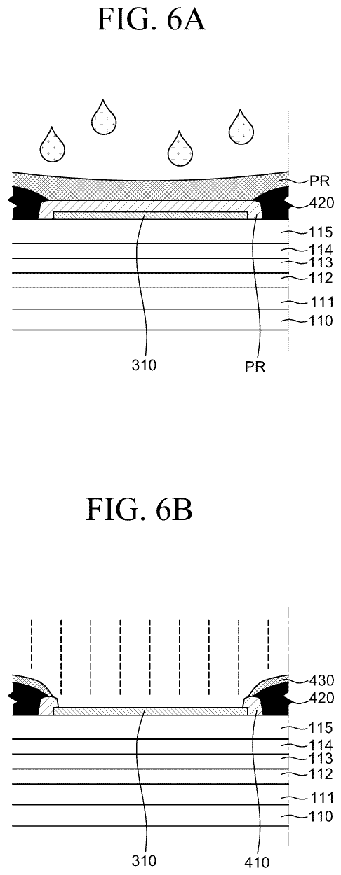

FIG. 6A and FIG. 6B are cross-sectional views for explaining another example of a process of removing some layers of the bank according to an exemplary aspect of the present disclosure.

First, referring to FIG. 6A, in a state where the material layer PPR for forming the third bank layer 430 is coated on the second bank layer 420 and the photo resist PR as shown in FIG. 4F, a strip process is performed. Thus, the photo resist PR and the material layer PR corresponding to the third bank layer 430 are stripped by a PR stripper to expose the pattern of the first electrode 310.

Then, referring to FIG. 6B, a rinse process is performed to the photo resist PR and the material layer PR corresponding to the third bank layer 430 from which the first electrode 310 is exposed.

The photo resist PR on the pattern of the first electrode 310 and the material layer PR corresponding to the third bank layer 430 are made of a photosensitive material of the same type. Therefore, the photo resist PR and the material layer PR may be removed together by the PR stripper. Meanwhile, the second bank layer 420 may be made of a material having stronger chemical properties with respect to the PR stripper than the photo resist PR on the pattern of the first electrode 310 and the material layer PR corresponding to the third bank layer 430. Therefore, the second bank layer 420 is not affected by the strip process.

As to the display apparatus 100 according to an exemplary aspect of the present disclosure, the process of removing the photo resist corresponding to the first bank layer 410 and the material layer corresponding to the third bank layer 430 using a mask may be applied as described above with reference to FIG. 5A and FIG. 5B. Alternatively, the process of chemically removing the photo resist and the material layer may be applied as described above with reference to FIG. 6A and FIG. 6B. Otherwise, a combination of the two processes may be applied. Herein, an order of applying the two removing processes is not limited.

Hereinafter, various examples of the shape of the bank according to an exemplary aspect of the present disclosure will be described with reference to FIG. 7 through FIG. 12.

For convenience in explanation, FIG. 7 through FIG. 12 do not illustrate substantially the same configuration as that of the display apparatus 100 described above with reference to FIG. 3.

FIG. 7 is a cross-sectional view illustrating an example of the shape of the bank according to an exemplary aspect of the present disclosure.

As shown in FIG. 7, the first bank layer 410 of the bank 400 is in contact with an end point (or edge) of the first electrode 310, and also covers a side surface and a part of an upper surface of the first electrode 310.

Herein, the second bank layer 420 is in contact with the outer portion of the first bank layer 410 disposed in the direction opposite to the direction toward the first electrode 310 based on the vertical line passing through the maximum height portion. Also, each of an end point (or edge) of the second bank layer 420 and an end point (or edge) of the third bank layer 430 may be in contact with a part of an upper surface of the first bank layer 410. Thus, the second bank layer 420 may be enclosed by the first bank layer 410 and the third bank layer 430.

Further, the second bank layer 420 and the third bank layer 430 may gradually decrease in height as being close to the first bank layer 410.

The above-described shape of the first bank layer 410 to the third bank layer 430 may be formed by the process of preparing the bank described above with reference to FIG. 4A and FIG. 6B.

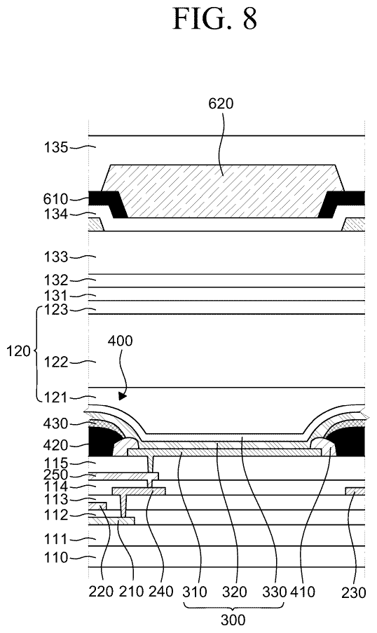

FIG. 8 is a cross-sectional view illustrating another example of the shape of the bank according to an exemplary aspect of the present disclosure.

As shown in FIG. 8, the first bank layer 410 of the bank 400 is in contact with the end point (or edge) of the first electrode 310, and also covers the side surface and a part of the upper surface of the first electrode 310.

Herein, the end point (or edge) of the second bank layer 420 may be in contact with the outer portion of the first bank layer 410, and the end point (or edge) of the third bank layer 430 may be in contact with the outer portion of the first bank layer 410. Thus, the second bank layer 420 may be enclosed by the first bank layer 410 and the third bank layer 430.

Also, the first bank layer 410 has an asymmetric shape with respect to a center line in a vertical direction, and has a shape in which the inner portion has a steeper slope than the outer portion.

The first bank layer 410 shown in FIG. 8 may have a similar height and a greater width compared to the first bank layer 410 shown in FIG. 7.

The above-described shape of the first bank layer 410 to the third bank layer 430 may be implemented by applying a different width of the photo resist PR coated on the metal layer of the first electrode 310 and a different shape of the mask in the process of preparing the bank described above with reference to FIG. 4A and FIG. 6B.

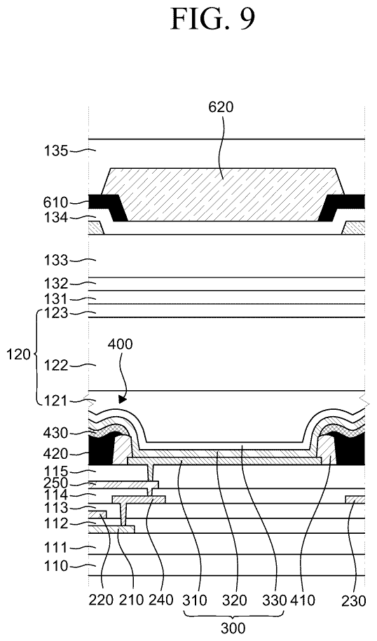

FIG. 9 is a cross-sectional view illustrating yet another example of the shape of the bank according to an exemplary aspect of the present disclosure.

As shown in FIG. 9, the first bank layer 410 of the bank 400 is in contact with the end point (or edge) of the first electrode 310, and also covers the side surface and a part of the upper surface of the first electrode 310.

Each of the end point (or edge) of the second bank layer 420 and the end point (or edge) of the third bank layer 430 may be in contact with the upper surface of the first bank layer 410.

Herein, a maximum height of a portion where the second bank layer 420 overlaps the first bank layer 410 in the vertical direction may be set greater than a maximum height of a portion where the second bank layer 420 does not overlap the first bank layer 410 in the vertical direction.

Also, the third bank layer 430 completely covers the second bank layer 420. Further, a maximum height of a portion where the third bank layer 430 overlaps the first bank layer 410 in the vertical direction may be set greater than a maximum height of a portion where the third bank layer 430 does not overlap the first bank layer 410 in the vertical direction. Thus, the second bank layer 420 may be enclosed by the first bank layer 410 and the third bank layer 430.

The first bank layer 410 shown in FIG. 9 may have a similar width and a greater maximum height compared to the first bank layer 410 shown in FIG. 7.

The above-described shape of the first bank layer 410 to the third bank layer 430 may be implemented by applying a different height of the photo resist PR coated on the metal layer of the first electrode 310 and a different shape of the mask in the process of preparing the bank described above with reference to FIG. 4A and FIG. 6B.

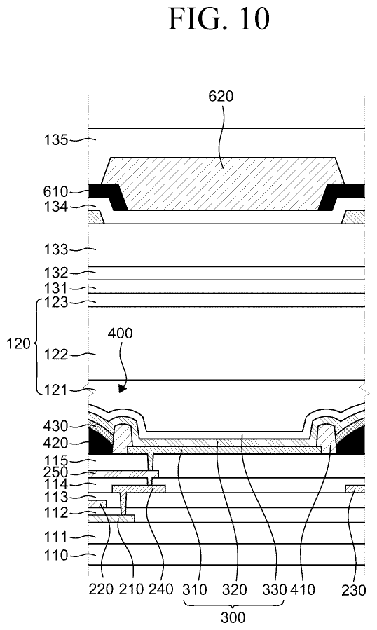

FIG. 10 is a cross-sectional view illustrating still another example of the shape of the bank according to an exemplary aspect of the present disclosure.

As shown in FIG. 10, the first bank layer 410 of the bank 400 is in contact with the end point (or edge) of the first electrode 310, and also covers the side surface and a part of the upper surface of the first electrode 310.

Herein, the end point (or edge) of the second bank layer 420 may be in contact with the outer portion of the first bank layer 410, and the end point (or edge) of the third bank layer 430 may be in contact with the outer portion of the first bank layer 410. Thus, the second bank layer 420 may be enclosed by the first bank layer 410 and the third bank layer 430.

Also, a height of the second bank layer 420 in a contact portion between the first bank layer 410 and the second bank layer 420 may be set smaller than a maximum height of the first bank layer 410. Further, a height of the third bank layer 430 in a contact portion between the first bank layer 410 and the third bank layer 430 may be set smaller than the maximum height of the first bank layer 410.

The first bank layer 410 shown in FIG. 10 may have a similar width and a greater maximum height compared to the first bank layer 410 shown in FIG. 7.

The above-described shape of the first bank layer 410 to the third bank layer 430 may be implemented by applying a different height of the photo resist PR coated on the metal layer of the first electrode 310 and a different shape of the mask in the process of preparing the bank described above with reference to FIG. 4A and FIG. 6B.

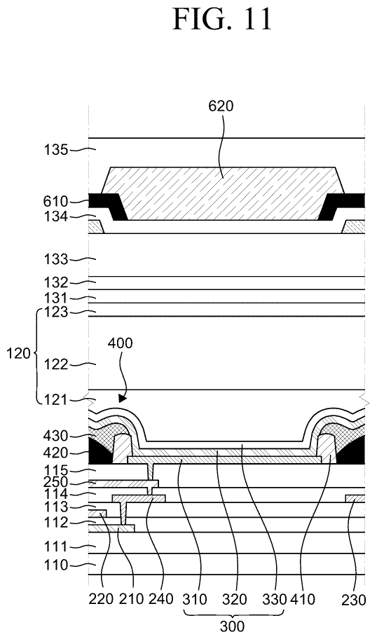

FIG. 11 is a cross-sectional view illustrating still another example of the shape of the bank according to an exemplary aspect of the present disclosure.

As shown in FIG. 11, the first bank layer 410 of the bank 400 is in contact with the end point (or edge) of the first electrode 310, and also covers the side surface and a part of the upper surface of the first electrode 310.

Herein, the end point (or edge) of the second bank layer 420 may be in contact with the outer portion of the first bank layer 410, and the third bank layer 430 may cover at least a part of the upper surface of the first bank layer 410. Thus, the second bank layer 420 may be enclosed by the first bank layer 410 and the third bank layer 430.

Also, a height of the third bank layer 430 in a portion where the first bank layer 410 overlaps the third bank layer 430 in the vertical direction may be set greater than a height of the third bank layer 430 in a part of a portion where the first bank layer 410 does not overlap the third bank layer 430 in the vertical direction.

The first bank layer 410 shown in FIG. 11 may have a similar width and a greater maximum height compared to the first bank layer 410 shown in FIG. 7.

The above-described shape of the first bank layer 410 to the third bank layer 430 may be implemented by applying a different height of the photo resist PR coated on the metal layer of the first electrode 310 and a different shape of the mask in the process of preparing the bank described above with reference to FIG. 4A and FIG. 6B.

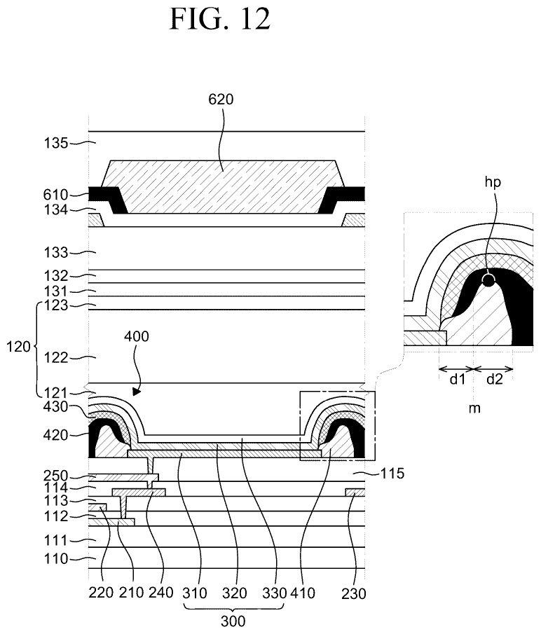

FIG. 12 is a cross-sectional view illustrating still another example of the shape of the bank according to an exemplary aspect of the present disclosure.

As shown in FIG. 12, the first bank layer 410 of the bank 400 is in contact with the end point (or edge) of the first electrode 310, and also covers the side surface and a part of the upper surface of the first electrode 310.

Herein, the first bank layer 410 may have an asymmetric shape with respect to the center line in a vertical direction. Also, the first bank layer 410 may have a shape in which the maximum height portion is located in an area opposite to an area where the first electrode 310 is disposed, based on the center line of the first bank layer 410.

Specifically, as shown in FIG. 12, one of vertical lines passing through the first bank layer 410 may be set as a center line m. Herein, a distance d1 from the center line m to an end point (or edge) of the inner portion of the first bank layer 410 is equal to a distance d2 from the center line m to an end point (or edge) of the outer portion of the first bank layer 410. Herein, a maximum height point hp of the first bank layer 410 may be located in an area opposite to an area where the first electrode 310 in contact with the first bank layer 410 is disposed, based on the center line m.

Also, each of the second bank layer 420 and the third bank layer 430 may cover all of the outer portion and a part of the inner portion of the first bank layer 410. Herein, the third bank layer 430 completely covers each of the second bank layer 420 and the first bank layer 410. Also, a contact portion between the end point (or edge) of the third bank layer 430 and the first bank layer 410 may be located more adjacent to the area where the first electrode 310 is disposed than a contact portion between the end point (or edge) of the second bank layer 420 and the first bank layer 410. Thus, the second bank layer 420 may be enclosed by the first bank layer 410 and the third bank layer 430.

The first bank layer 410 shown in FIG. 12 may have a greater width and a greater maximum height than the first bank layer 410 shown in each of FIG. 7 through FIG. 11.

The above-described shape of the first bank layer 410 to the third bank layer 430 may be implemented by applying different height and width of the photo resist PR coated on the metal layer of the first electrode 310 and a different shape of the mask in the process of preparing the bank described above with reference to FIG. 4A and FIG. 6B.

The display apparatus 100 according to another exemplary aspect of the present disclosure may further a spacer. The spacer is disposed together with the first bank layer 410 described above with reference to FIG. 7 through FIG. 11 and configured to maintain a uniform gap with the laminated structure disposed thereabove.

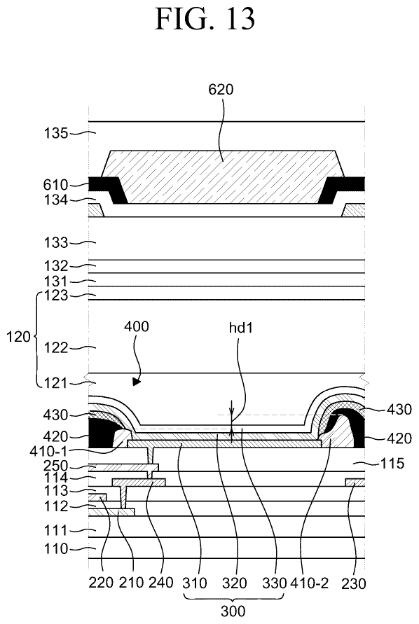

The spacer according to another exemplary aspect of the present disclosure may have the same shape as the first bank layer 410 shown in FIG. 12, and may be included as a part of the bank 400. Hereinafter, various examples of the shape of the bank according to another exemplary aspect of the present disclosure will be described with reference to FIG. 13 through FIG. 17.

FIG. 13 through FIG. 17 do not illustrate substantially the same parts as the configuration of the display apparatus 100 described above with reference to FIG. 3 and various shapes of the bank described above with reference to FIG. 7 through FIG. 12.

FIG. 13 is a cross-sectional view illustrating an example of the shape of the bank according to another exemplary aspect of the present disclosure.

A part of the bank 400 disposed on the planarization layer 115 may have any one of the shapes of the first bank layer 410 described above with reference to FIG. 7 through FIG. 11. Also, another part of the bank 400 may include a first bank layer 410-1 having any one of the shapes of the first bank layer 410 described above with reference to FIG. 7 through FIG. 11 and a fourth bank layer 410-2 having the same shape as the first bank layer 410 described above with reference to FIG. 12.

As shown in FIG. 13, the first bank layer 410-1 included in the bank 400 may be identical or similar in shape to the first bank layer 410 described above with reference to FIG. 7. Also, the fourth bank layer 410-2 included in the bank 400 may be identical or similar in shape to the first bank layer 410 described above with reference to FIG. 12.

The second bank layer 420 included in the bank 400 covers an outer portion and a part of an inner portion of the fourth bank layer 410-2. The third bank layer 430 completely covers the second bank layer 420 and the fourth bank layer 410-2.

Also, the fourth bank layer 410-2 may have an asymmetric shape. Further, a maximum height portion of the fourth bank layer 410-2 may be located in an area opposite to an area where the first electrode 310 is disposed, based on a center line in the vertical direction of the fourth bank layer 410-2.

The fourth bank layer 410-2 may be made of the same material and provided on the same layer as the first bank layer 410-1.

Herein, the fourth bank layer 410-2 included in the bank 400 may be in contact with the end point (or edge) of the first electrode 310, and may have a greater height than the first bank layer 410-1. Also, the fourth bank layer 410-2 may have a greater width than the first bank layer 410-1.

As shown in FIG. 13, a maximum height portion of the first bank layer 410-1 may have a difference of a first height hd1 from a maximum height portion of the fourth bank layer 410-2.

For example, the first height hd1 may be equal to or greater than the height of the first bank layer 410 described above with reference to FIG. 7. This may be implemented by coating the photo resist PR on the metal layer for forming the first electrode 310 twice or more in the process of preparing the bank described above with reference to FIG. 4A and FIG. 6B.

The width of the fourth bank layer 410-2 may be implemented by applying a different shape of the mask for exposing the photo resist PR coated on the metal layer for forming the first electrode 310 in the process of preparing the bank described above with reference to FIG. 4A and FIG. 6B.

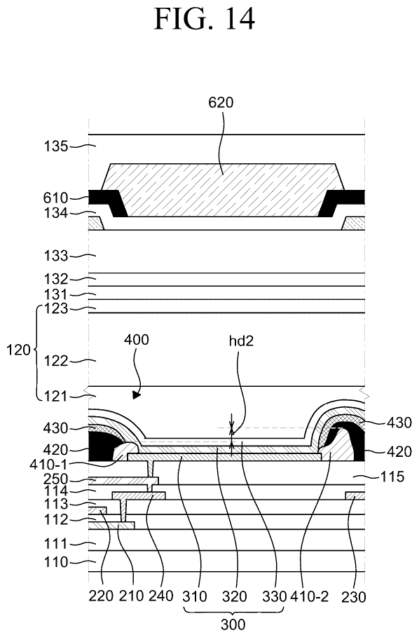

FIG. 14 is a cross-sectional view illustrating another example of the shape of the bank according to another exemplary aspect of the present disclosure.

As shown in FIG. 14, the first bank layer 410-1 included in the bank 400 may be identical or similar in shape to the first bank layer 410 described above with reference to FIG. 8. Also, the fourth bank layer 410-2 included in the bank 400 may be identical or similar in shape to the fourth bank layer 410-2 described above with reference to FIG. 13.

Herein, as shown in FIG. 14, the maximum height portion of the first bank layer 410-1 may have a difference of a second height hd2 from the maximum height portion of the fourth bank layer 410-2.

For example, the second height hd2 may be equal to or greater than the height of the first bank layer 410 described above with reference to FIG. 8. The second height hd2 may be similar or identical to the first height hd1 described above with reference to FIG. 13.

Also, the fourth bank layer 410-2 may be identical or similar in width to the first bank layer 410-1.

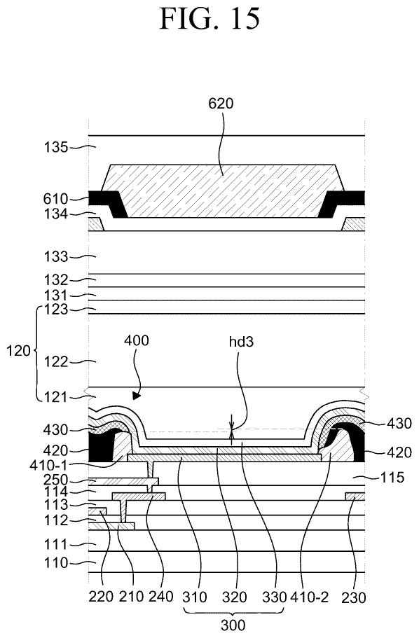

FIG. 15 is a cross-sectional view illustrating yet another example of the shape of the bank according to another exemplary aspect of the present disclosure.

As shown in FIG. 15, the first bank layer 410-1 included in the bank 400 may be identical or similar in shape to the first bank layer 410 described above with reference to FIG. 9. Also, the fourth bank layer 410-2 included in the bank 400 may be identical or similar in shape to the fourth bank layer 410-2 described above with reference to FIG. 13.

Herein, as shown in FIG. 15, the maximum height portion of the first bank layer 410-1 may have a difference of a third height hd3 from the maximum height portion of the fourth bank layer 410-2.

For example, the third height hd3 may be smaller than the height of the first bank layer 410 described above with reference to FIG. 9. The third height hd3 may be smaller than the first height hd1 and the second height hd2 described above with reference to FIG. 13 and FIG. 14, respectively.

Also, the fourth bank layer 410-2 may have a greater width than the first bank layer 410-1.

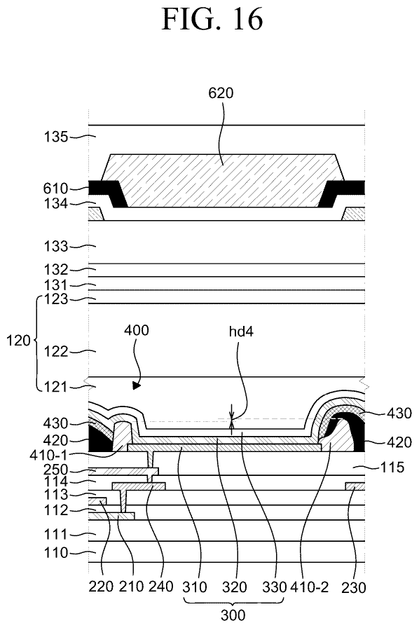

FIG. 16 is a cross-sectional view illustrating still another example of the shape of the bank according to another exemplary aspect of the present disclosure.

As shown in FIG. 16, the first bank layer 410-1 included in the bank 400 may be identical or similar in shape to the first bank layer 410 described above with reference to FIG. 10. Also, the fourth bank layer 410-2 included in the bank 400 may be identical or similar in shape to the fourth bank layer 410-2 described above with reference to FIG. 13.

Herein, as shown in FIG. 16, the maximum height portion of the first bank layer 410-1 may have a difference of a fourth height hd4 from the maximum height portion of the fourth bank layer 410-2.

For example, the fourth height hd4 may be smaller than the height of the first bank layer 410 described above with reference to FIG. 10. The fourth height hd4 may be smaller than the first height hd1 and the second height hd2 described above with reference to FIG. 13 and FIG. 14, respectively.

Also, the fourth bank layer 410-2 may have a greater width than the first bank layer 410-1.

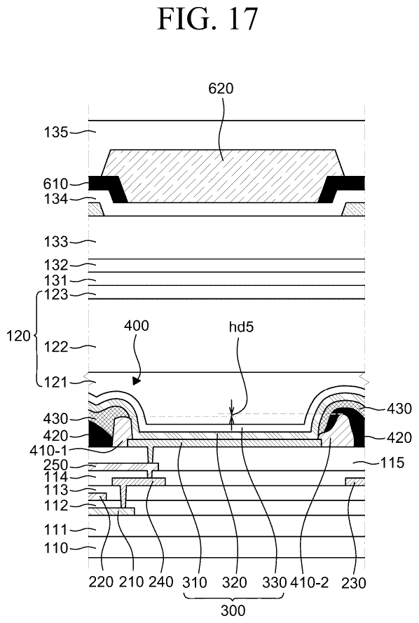

FIG. 17 is a cross-sectional view illustrating still another example of the shape of the bank according to another exemplary aspect of the present disclosure.

As shown in FIG. 17, the first bank layer 410-1 included in the bank 400 may be identical or similar in shape to the first bank layer 410 described above with reference to FIG. 11. Also, the fourth bank layer 410-2 included in the bank 400 may be identical or similar in shape to the fourth bank layer 410-2 described above with reference to FIG. 13.

Herein, as shown in FIG. 17, the maximum height portion of the first bank layer 410-1 may have a difference of a fifth height hd5 from the maximum height portion of the fourth bank layer 410-2.

For example, the fifth height hd5 may be smaller than the height of the first bank layer 410 described above with reference to FIG. 11. The fifth height hd5 may be smaller than the first height hd1 and the second height hd2 described above with reference to FIG. 13 and FIG. 14, respectively.

Also, the fourth bank layer 410-2 may have a greater width than the first bank layer 410-1.

With the bank 400 having various shapes as described above with reference to FIG. 7 through FIG. 17, it is possible to enhance the reliability of the display apparatus 100 by suppressing oxidation and contamination of the surface of the first electrode 310 in the light emitting element 300. Also, it is possible to selectively adjust a slope of a bank adjacent to an emission area of a sub-pixel. Thus, it is possible to secure a low reflection structure for a light emitting element and also possible to suppress the flow of an excessive light leakage current (LLC) to a boundary between light emitting elements. As described above, it is possible to minimize a potential probability of defects such as contamination or oxidation of the display apparatus. Therefore, a lifetime of the display apparatus may be improved, and, thus, production energy may be reduced, which enables driving with low power consumption.

The exemplary aspects of the present disclosure may also be described as follows:

According to an aspect of the present disclosure, there is provided a display apparatus. The display apparatus includes a substrate including a display area in which a plurality of pixels is defined and a non-display area which does not overlap the display area. The display apparatus further includes a plurality of light emitting elements each including a first electrode, an emission layer, and a second electrode which are sequentially laminated on the substrate in the display area. The display apparatus further includes a bank disposed on the substrate and covering an end point (or edge) of the first electrode. At least a part of the bank includes: a first bank layer which is in contact with the end point (or edge) of the first electrode and includes an inner portion in a direction toward the first electrode based on a vertical line passing through a maximum height portion and an outer portion opposite to the inner portion; a second bank layer disposed to be in contact with the outer portion of the first bank layer; and a third bank layer disposed on the second bank layer. The second bank layer is enclosed by at least one of the first bank layer and the third bank layer.

An end point (or edge) of the second bank layer may be in contact with the outer portion of the first bank layer, and an end point (or edge) of the third bank layer may be in contact with the outer portion of the first bank layer.

A height of the second bank layer in a contact portion between the first bank layer and the second bank layer may be smaller than a maximum height of the first bank layer, and a height of the third bank layer in a contact portion between the first bank layer and the third bank layer may be smaller than the maximum height of the first bank layer.

The first bank layer may have an asymmetric shape, and the inner portion of the first bank layer may have a steeper slope than the outer portion.

An end point (or edge) of the second bank layer may be in contact with the outer portion of the first bank layer, and the third bank layer may cover at least a part of an upper surface of the first bank layer.

An end point (or edge) of the second bank layer and an end point (or edge) of the third bank layer may be in contact with an upper surface of the first bank layer.

The second bank layer and the third bank layer may gradually decrease in height as being close to the first bank layer.

A maximum height of a portion where the second bank layer overlaps the first bank layer may be set greater than a maximum height of a portion where the second bank layer does not overlap the first bank layer. A maximum height of a portion where the third bank layer overlaps the first bank layer may be set greater than a maximum height of a portion where the third bank layer does not overlap the first bank layer.

The first bank layer may have an asymmetric shape. A maximum height portion of the first bank layer may be located in an area opposite to an area where the first electrode is disposed, based on a center line in a vertical direction of the first bank layer.

The second bank layer and the third bank layer may cover all of the outer portion and a part of the inner portion of the first bank layer.

The third bank layer may completely cover the first bank layer.

Another part of the bank may further include a fourth bank layer which is in contact with the end point (or edge) of the first electrode and has a greater height than the first bank layer. In another part of the bank, the second bank layer may cover an outer portion and a part of an inner portion of the fourth bank layer. The third bank layer may completely cover the second bank layer and the fourth bank layer.

The fourth bank layer may be made of the same material and provided on the same layer as the first bank layer.

The fourth bank layer may have a greater width than the first bank layer.

The first bank layer and the third bank layer may be made of the same material.

Each of the first bank layer and the third bank layer may be made of a transparent material, and the second bank layer may contain a black material.

The display apparatus may further include: a thin film transistor disposed on the substrate and electrically connected to the light emitting element; an insulating material disposed on the thin film transistor; a planarization layer disposed on the insulating layer; and an encapsulation layer covering the light emitting element and the bank. The first electrode, the first bank layer, and the second bank layer are disposed on the planarization layer.

The display apparatus may further include: a touch buffer layer disposed on the encapsulation layer; a plurality of touch electrodes disposed on the touch buffer layer; and a touch electrode protection layer disposed on the plurality of touch electrodes. The touch electrode overlaps the bank.

The display apparatus may further include: a light shielding layer disposed on the encapsulation layer and including an opening overlapping the light emitting element; a color filter disposed on the light shielding layer and filling in the opening of the light shielding layer; and an overcoating layer covering the color filter. The light shielding layer overlaps the bank.

Each of the first bank layer, the second bank layer, and the third bank layer may be made of an organic material.

Although the exemplary aspects of the present disclosure have been described in detail with reference to the accompanying drawings, the present disclosure is not limited thereto and may be embodied in many different forms without departing from the technical concept of the present disclosure. Therefore, the exemplary aspects of the present disclosure are provided for illustrative purposes only but not intended to limit the technical concept of the present disclosure. The scope of the technical concept of the present disclosure is not limited thereto. Therefore, it should be understood that the above-described exemplary aspects are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display apparatus, comprising:
a substrate including a display area in which a plurality of pixels is defined and a non-display area which does not overlap the display area;
a plurality of light emitting elements each including a first electrode, an emission layer, and a second electrode which are sequentially laminated on the substrate in the display area; and
a bank disposed on the substrate and covering an edge of the first electrode,
wherein at least a part of the bank includes:
a first bank layer being in contact with the edge of the first electrode and including an inner portion in a direction toward the first electrode with respect to a vertical line passing through a maximum height portion and an outer portion opposite to the inner portion;
a second bank layer being in contact with the outer portion of the first bank layer; and
a third bank layer disposed on the second bank layer,
wherein the second bank layer is enclosed by at least one of the first bank layer and the third bank layer.

2. The display apparatus according to claim 1, wherein an edge of the second bank layer is in contact with the outer portion of the first bank layer, and
wherein an edge of the third bank layer is in contact with the outer portion of the first bank layer.

3. The display apparatus according to claim 2, wherein a height of the second bank layer in a contact portion between the first bank layer and the second bank layer is smaller than the maximum height of the first bank layer, and
wherein a height of the third bank layer in a contact portion between the first bank layer and the third bank layer is smaller than the maximum height of the first bank layer.

4. The display apparatus according to claim 2, wherein the first bank layer has an asymmetric shape, and
wherein the inner portion of the first bank layer has a slope steeper than the outer portion.

5. The display apparatus according to claim 1, wherein an edge of the second bank layer is in contact with the outer portion of the first bank layer, and
wherein the third bank layer covers at least a part of an upper surface of the first bank layer.

6. The display apparatus according to claim 1, wherein an edge of the second bank layer and an edge of the third bank layer are in contact with an upper surface of the first bank layer.

7. The display apparatus according to claim 6, wherein the second bank layer and the third bank layer gradually decrease in height as being close to the first bank layer.

8. The display apparatus according to claim 6, wherein a maximum height a portion where the second bank layer overlaps the first bank layer is greater than a maximum height portion where the second bank layer does not overlap the first bank layer, and
wherein a maximum height portion where the third bank layer overlaps the first bank layer is greater than a maximum height portion where the third bank layer does not overlap the first bank layer.

9. The display apparatus according to claim 1, wherein the first bank layer has an asymmetric shape, and
wherein a maximum height portion of the first bank layer is located in an area opposite to an area where the first electrode is disposed with respect to a center line in a vertical direction of the first bank layer.

10. The display apparatus according to claim 9, wherein the second bank layer and the third bank layer cover all of the outer portion and a part of the inner portion of the first bank layer.

11. The display apparatus according to claim 9, wherein the third bank layer completely covers the first bank layer.

12. The display apparatus according to claim 1, wherein the bank further includes a fourth bank layer which is in contact with an edge of the first electrode and has a height greater than the first bank layer,
wherein the second bank layer covers an outer portion and a part of an inner portion of the fourth bank layer, and
wherein the third bank layer completely covers the second bank layer and the fourth bank layer.

13. The display apparatus according to claim 12, wherein the fourth bank layer is formed of a same material and disposed on a same layer as the first bank layer.

14. The display apparatus according to claim 12, wherein the fourth bank layer has a width greater than the first bank layer.

15. The display apparatus according to claim 1, wherein the first bank layer and the third bank layer are formed of a same material.

16. The display apparatus according to claim 1, wherein the first bank layer and the third bank layer are formed of a transparent material, and the second bank layer is formed of a black material.

17. The display apparatus according to claim 1, further comprising:
a thin film transistor disposed on the substrate and electrically connected to the light emitting element;
an insulating material disposed on the thin film transistor;
a planarization layer disposed on the insulating layer; and
an encapsulation layer covering the light emitting element and the bank,
wherein the first electrode, the first bank layer, and the second bank layer are disposed on the planarization layer.

18. The display apparatus according to claim 17, further comprising:
a touch buffer layer disposed on the encapsulation layer;
a plurality of touch electrodes disposed on the touch buffer layer; and
a touch electrode protection layer disposed on the plurality of touch electrodes,
wherein the touch electrode overlaps the bank.

19. The display apparatus according to claim 17, further comprising:
a light shielding layer disposed on the encapsulation layer and having an opening overlapping the light emitting element;
a color filter disposed on the light shielding layer and filling in the opening of the light shielding layer; and
an overcoating layer covering the color filter,
wherein the light shielding layer overlaps the bank.

20. The display apparatus according to claim 1, wherein the first bank layer, the second bank layer, and the third bank layer are formed of an organic material.

21. A display apparatus, comprising:
a substrate including a display area in which a plurality of pixels is defined;
a light emitting element including a first electrode, an emission layer disposed on the first electrode and a second electrode disposed on the emission layer in the display area;
a first bank layer being in contact with the first electrode and the light emitting layer and having an inner portion facing the light emitting element and an outer portion opposite to the inner portion;
a second bank layer being in contact with the outer portion of the first bank layer; and
a third bank layer being in contact the first bank layer and disposed on the second bank layer,
wherein the first bank layer and the third bank layer enclose the second bank layer,
wherein the second bank layer does not overlap the first electrode, and
wherein the first bank layer and the second bank layer are formed of different materials, and the first bank layer and the third bank layer are formed of a same material.

22. The display apparatus according to claim 21, further comprising a fourth bank layer being in contact with an edge of the first electrode and has a height greater than the first bank layer.

23. The display apparatus according to claim 22, wherein the second bank layer covers the fourth bank layer, and
wherein the third bank layer covers the second bank layer and the fourth bank layer.
